(19) United States
(12) Patent Application Publication
(10) Pub. No.: US 2007/0064400 A1
(43) Pub. Date: Mar. 22, 2007

(54) Information apparatus and display control method

(75) Inventor: Toshikazu Morisawa, Tokorozawa-shi (JP)

Correspondence Address: PILLSBURY WINTHROP SHAW PITTMAN, LLP, P.O. BOX 10500, MCLEAN, VA, 22102, US

(73) Assignee: Kabushiki Kaisha Toshiba, Tokyo (JP)

(21) Appl. No.: 11/375,047

(22) Filed: Mar. 15, 2006

(30) Foreign Application Priority Data
Mar. 15, 2005 (JP) 2005-073944

(51) Int. Cl. H05K 5/00

(52) U.S. Cl. 361/724

(57) ABSTRACT

According to one embodiment, there is provided an information apparatus including a body, a cover capable of being opened and closed with respect to the body, a first display unit provided in the cover, and a second display unit provided with a battery and attachable to and detachable from the body or the cover, the second display being capable of displaying information and charging the battery with power supplied from the body in an attached state, and displaying information with power of the battery in a detached state.

### CROSS-REFERENCE TO RELATED APPLICATIONS

This application is based upon and claims the benefit of priority from Japanese Patent Application No. 2005-073944, filed Mar. 15, 2005, the entire contents of which are incorporated herein by reference.

### BACKGROUND

1. Field

One embodiment of the invention relates to an information apparatus having a display unit and an auxiliary display unit, and a display control method.

2. Description of the Related Art

An information apparatus, such as a notebook computer, is generally equipped with a cover, which is capable of being opened and closed with respect to the main body of the information apparatus. The cover includes a display unit to display information. Some type of information apparatus has an auxiliary display unit in addition to the above-mentioned display unit, for example, in a front portion of the main body, to display a condition of the power source or the like of the information apparatus. The auxiliary display unit may be provided in the cover. It is well known that the auxiliary display unit is provided in a required part of the information apparatus.

For example, Jpn. Pat. Appln. KOKAI Publication No. 2000-267758 (hereinafter referred to as Document 1) discloses a structure including a main display panel and a smaller auxiliary display device, which is provided in the housing and displays the same information as that displayed in the main display panel. Further, Jpn. Pat. Appln. KOKAI Publication No. 2001-242955 (hereinafter referred to as Document 2) discloses that an auxiliary display device is detachably attached on the same plane as the keyboard surface of the housing, and used as a partial display area of the main display.

An information apparatus, e.g., a notebook computer, is often carried about in a bag or the like. During the carriage, the user cannot easily refer to information (for example, information on received email) in the information apparatus. Since the main display unit or the auxiliary display unit of the information apparatus is generally fixed to the main body of the information apparatus, it is difficult to see formation through the display unit.

Document 1 does not disclose that the auxiliary display unit is detachably attached to the main body of the information apparatus, but Document 2 does. However, the auxiliary display unit disclosed in Document 2 cannot be used in the state where it is separated from the main body of the information apparatus.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary diagram showing a first example of placement and mechanism of an auxiliary display unit in an information apparatus according to an embodiment of the present invention;

FIG. 2 is an exemplary diagram showing a second example of placement and mechanism of an auxiliary display unit in the information apparatus according to the embodiment of the present invention;

FIG. 3 is an exemplary block diagram showing a configuration of the information apparatus;

FIG. 4 is an exemplary diagram showing an example of setting information relating to controls with respect to various devices for use in a control unit or a sub-CPU;

FIG. 5 is an exemplary diagram showing an example of setting information relating to display control for use in the control unit or the sub-CPU;

FIG. 6 is an exemplary diagram showing an example of setting information relating to power control for use in the control unit or the sub-CPU;

FIG. 7 is an exemplary flowchart for explaining an operation relating to presetting; and

FIG. 8 is an exemplary flowchart for explaining an operation relating to setting based on set information.

### DETAILED DESCRIPTION

Various embodiments according to the invention will be described hereinafter with reference to the accompanying drawings. In general, according to one embodiment of the invention, there is provided an information apparatus including a body, a cover capable of being opened and closed with respect to the body, a first display unit provided in the cover, and a second display unit provided with a battery and attachable to and detachable from the body or the cover, the second display being capable of displaying information and charging the battery with power supplied from the body in an attached state, and displaying information with power of the battery in a detached state.

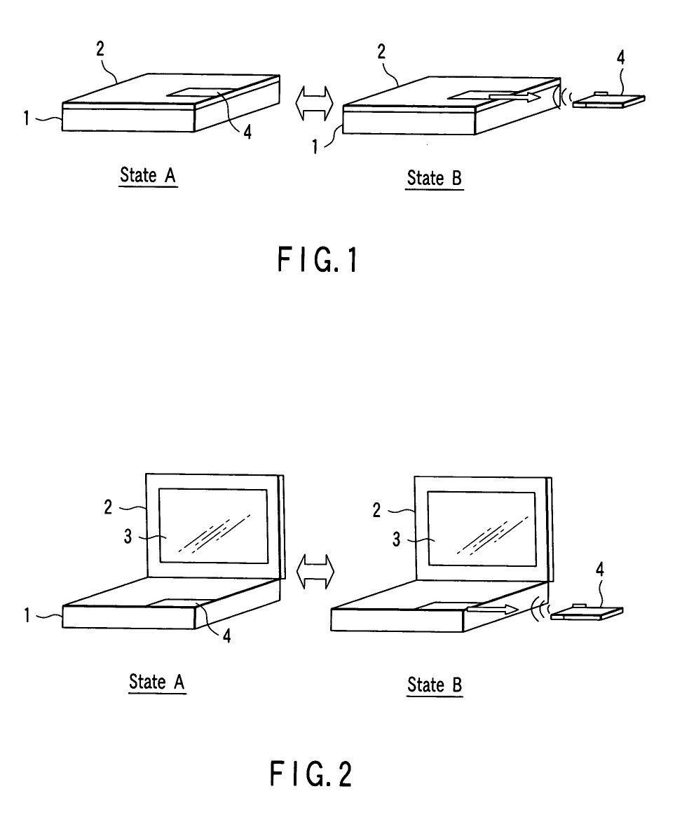

First, two examples of placement and mechanism of an auxiliary display unit in an information apparatus according to the embodiment of the present invention will be described with reference to FIGS. 1 and 2. FIG. 1 shows the first example, and FIG. 2 shows the second example.

The information apparatus shown in FIGS. 1 and 2 is, for example, a notebook computer, which has an main body 1 and a cover 2. The cover 2 includes a main display unit (main LCD) 3 and is capable of being opened and closed with respect to the main body 1.

An auxiliary display unit (sub-LCD) 4 has a battery to be described later, and can be mounted on (attached to) and separated from (detached from) the main body 1 or the cover 2. When mounted, the auxiliary display unit 4 is electrically and mechanically connected to the main body 1 via a connecting portion (e.g., a connector). In the attached state as described above, the auxiliary display unit 4 displays information and charges the battery by using the power supplied from the main body 1. In the detached state, it displays information by using the power of the battery.

Further, the auxiliary display unit 4 has a wireless communication device (communicating section) to be described later, so that it can display information obtained from the main body through the wireless communication device in the detached state. In the attached state also, the auxiliary display unit can display information obtained from the main body through the wireless communication device. In this case, information communication may be performed via a wired communication device, without using the wireless communication device.

In this embodiment, it is assumed that the operating system of the information apparatus is running, regardless of whether the cover 2 is opened or closed, and that the auxiliary display unit 4 displays information obtained while the operating system is running. In short, the auxiliary display unit 4 can display information regardless of whether the cover is opened or closed. If display is unnecessary, the information apparatus can be set to a non-display state.

In the first example shown in FIG. 1, the auxiliary display unit 4 is attachable to and detachable from the connecting portion (connector or the like) on the upper surface of the cover 2. In the state A shown in FIG. 1, the screen of the auxiliary display unit 4 faces up and is visible to the user. When the user is going to remove the auxiliary display unit 4 from the main body 1, he or she pulls the auxiliary display unit 4 in the direction of the arrow. In the state B shown in FIG. 1, the auxiliary display unit 4 is separated from the main body 1. Since the auxiliary display unit 4 is battery-driven, the user can see the screen.

In the second example shown in FIG. 2, the auxiliary display unit 4 is attachable to and detachable from the connecting portion (connector or the like) on the upper surface of the main body 1 while the cover 2 is opened. In the state A shown in FIG. 2, the screen of the auxiliary display unit 4 faces up and is visible to the user. When the user is going to remove the auxiliary display unit 4 from the main body 1, he or she pulls the auxiliary display unit 4 in the direction of the arrow. In the state B shown in FIG. 2, the auxiliary display unit 4 is separated from the main body 1. Since the auxiliary display unit 4 is battery-driven, the user can see the screen.

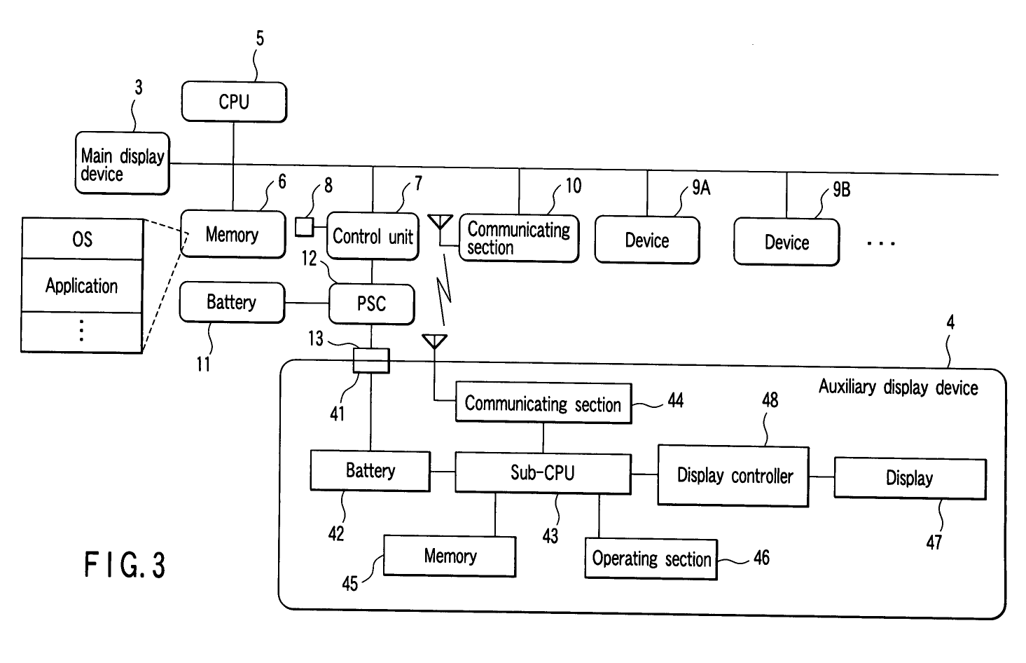

FIG. 3 is a block diagram showing a configuration of the above information apparatus. In FIG. 3, the same elements as those shown in FIGS. 1 and 2 are identified by the same reference numerals as used in those figures.

In addition to the main display unit 3 and the auxiliary display unit 4 described above, the information apparatus includes, in the main body 1, a CPU 5, a memory 6, a control unit 7, an operating unit 8, devices 9A, 9B, etc., a communicating section (wireless communication device) 10, a battery 11, a power supply controller (PSC) 12, a connecting portion 13, etc. The auxiliary display unit 4 includes a connecting section 41, a battery 42, a sub-CPU 43, a communicating section (wireless communication device) 44, a memory 45, an operating section 46, a display 47, a display controller 48, etc.

The CPU 5 controls the overall operation of the information apparatus. It executes programs resident in, for example, the memory 6, thereby performing various display control and power control with respect to the main display unit 3 and the auxiliary display unit 4.

The memory 6 is a non-volatile memory, which stores the operating system (OS), various applications (software for email, etc.) and drivers.

The control unit 7 is a control device, which manages power supply and displays. When the control unit 7 detects depression of any of various operation buttons, including the power supply button, it performs a setting process or a setting change process relating to the power supply condition (the power supply mode, power-saving mode, power supply stop mode, etc.) and a display content of the main display unit 3 and the auxiliary display unit 4 based on the setting information preset in a register or the like. It also performs a process for storing necessary information, an information reading process, a transfer process, a resetting process, etc., when a rebooting, suspending or resuming process is performed. The control unit 7 also performs control to cause the auxiliary display unit 4 to display information (contents of received mail, etc.), which is obtained from the main body side while the OS is running. Further, when the rebooting is carried out by restarting the OS, the control unit 7 also performs control to cause the auxiliary display unit 4 to display information, which is obtained from the main body side. Furthermore, the control unit 7 performs a refresh operation in response to an instruction from the auxiliary display unit 4.

The operating unit 8 has a power supply button to instruct a power on/off operation of the main body, an operation button to instruct a refreshing operation (including a refreshing operation or sync operation relating to the power supply condition or the display content of the auxiliary display unit 4), operation buttons to instruct changing of the setting conditions respectively relating to the power supply condition and the display content of the main display unit 3 and the auxiliary display unit 4.

The devices 9A, 9B, etc. are connected to a system bus. They include a magnetic disk drive (HDD), an optical disk drive (ODD), a graphics controller, etc. Each of these devices is controlled by, for example, the control unit 7, so that the operating condition is changed in accordance with the attached or detached state of the auxiliary display unit 4 (for example, the device is controlled so as to change the non-use time, which is a condition for switching the device to the power-saving mode or the stop mode).

The communicating section 10 performs wireless communication with the communicating section 44 of the auxiliary display unit 4. It can carry out an interface process (process relating to control information or display information) between the control unit 7 of the main body 1 and the sub-CPU 43 of the auxiliary display unit 4.

The battery 11 is a rechargeable cell provided in the main body 1.

The power supply controller 12 controls power supply to the respective sections of the information apparatus. It also controls charges of the battery 11 of the main body 1 and the battery 42 of the auxiliary display unit 4.

The connecting portion 13 is a connector provided in the main body 1. It electrically connects or disconnects the main body 1 to or from the connecting portion 41 of the auxiliary display unit 4.

The connecting portion 41 is a connector provided in the auxiliary display unit 4. It electrically connects or disconnects the auxiliary display unit 4 to or from the connecting portion 13 of the main body 1.

The battery 42 is a rechargeable cell provided in the auxiliary display unit 4. The battery 42 is charged with power supplied from the power supply controller 12, in the state where the connecting portion 41 is connected to the connecting portion 13 of the main body 1.

The sub-CPU 43 controls the operations of the auxiliary display unit 4. By monitoring the condition of the battery 42 or the connecting portion 41, the sub-CPU 43 detects whether the auxiliary display unit 4 is connected to the main body 1 (or the cover 2). Through the communicating section 44, the sub-CPU 43 communicates with the control unit 7: it obtains various information (the contents of received email, the number of received email items, the amount of electricity remaining in the battery, the wireless signal level, the date and time, etc.) from the main body 1, and sends a refreshing instruction to the main body 1. Further, when the sub-CPU 43 detects a signal from the operating section 46, it performs a setting process or a setting change process relating to the power supply condition and the display content of the auxiliary display unit 4 based on the setting information preset in the memory 45 or the like.

The communicating section 44 performs wireless communication with the communicating section 10 of the main body 1. It can carry out an interface process (process relating to control information or display information) between the control unit 7 of the main body 1 and the sub-CPU 43 of the auxiliary display unit 4.

The memory 45 stores setting information relating to the power supply condition and the display content of the auxiliary display unit 4 or a display 47.

The operating section 46 has a power supply button to instruct a power on/off operation of the auxiliary display unit 4, an operation button to instruct a refreshing operation or sync operation relating to the power supply condition or the display content of the auxiliary display unit 4, operation buttons to instruct changing of the setting conditions respectively relating to the power supply condition and the display content, etc. of the auxiliary display unit 4. The operating section 46 may be a touch panel laid over the display 47. The operating section 46 may be configured such that the function thereof in the state where the auxiliary display unit 4 is mounted on the main body 1 is different from that in the state where it is separated from the main body 1. For example, the operating section 46 may be controlled by the sub-CPU 43 such that the touch panel function is enabled while the auxiliary display unit 4 is mounted on the main body 1, but disabled while the auxiliary display unit 4 is separated from the main body 1. Further, the operating section 46 may be controlled such that the display function of the display 47 is disabled, while the auxiliary display unit 4 is mounted on the main body 1.

The display 47 displays information in accordance with instructions from a display controller 48.

The display controller 48 performs display control with respect to the display 47.

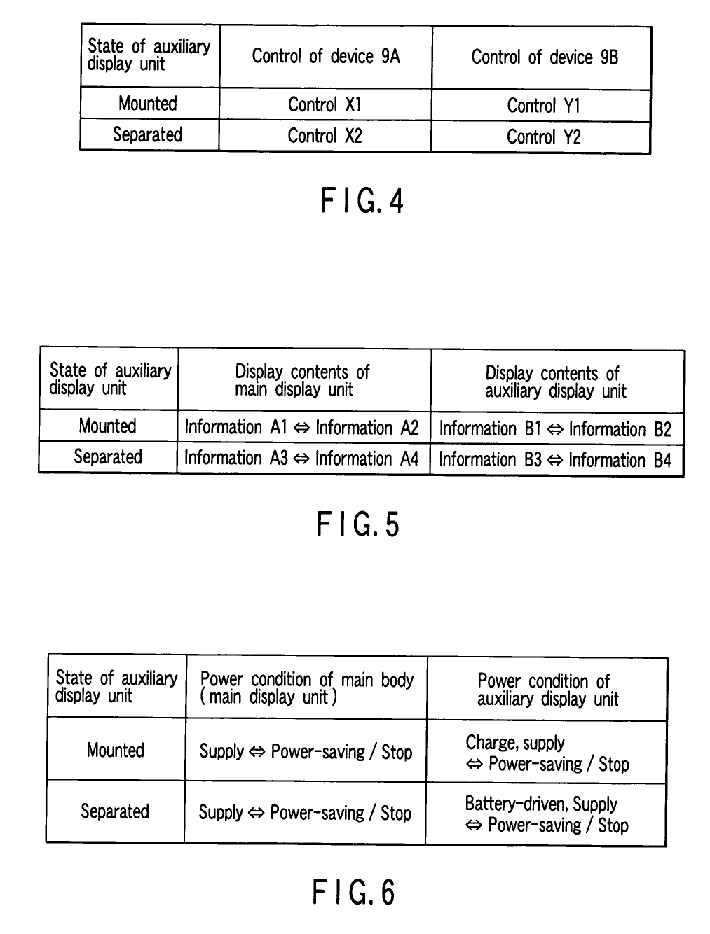

FIG. 4 is a diagram showing an example of setting information relating to control of the devices 9A and 9B for use in the control unit 7 or the sub-CPU 43. The setting information can be preset by the user through the control unit 7 or the sub-CPU 43.

In the state where the auxiliary display unit 4 is mounted on the main body 1, for example, control X1 is applied to the device 9A and control Y1 is applied to the device 9B. On the other hand, in the state where the auxiliary display unit 4 is separated from the main body 1, for example, control X2 is applied to the device 9A and control Y2 is applied to the device 9B.

If the device 9A is a magnetic disk drive, it may be controlled so as to change the non-use time, which is a condition for switching the device to the power-saving mode or the stop mode, in accordance with the attached or detached state of the auxiliary display unit 4. In this case, if the auxiliary display unit 4 is separated from the main body 1, the possibility of the user using the main body 1 is low. Therefore, the non-use time is shortened so that the device can be switched to the power-saving mode or the stop mode earlier (for example, the time to be monitored is changed from 5 minutes to 1 minute). As a result, the power consumption in the main body 1 can be reduced.

FIG. 5 is a diagram showing an example of setting information relating to display control for use in the control unit 7 or the sub-CPU 43. The setting information can be preset by the user through the control unit 7 or the sub-CPU 43.

In the state where the auxiliary display unit 4 is mounted on the main body 1, the main display unit 3 displays, for example, information A1, and the auxiliary display unit 4 displays, for example, information B1. In this state, if the user performs an operation to change the display content of the main display unit 3, the information A1 is changed to another information: for example, information A2. Of course, it is possible to return the display content to the original state through an operation by the user. If the user performs an operation to change the display content of the auxiliary display unit 4, the information B1 is changed to another information: for example, information B2. Of course, it is possible to return the display content to the original state through an operation by the user.

In the state where the auxiliary display unit 4 is separated from the main body 1, the main display unit 3 displays, for example, information A3, and the auxiliary display unit 4 displays, for example, information B3. In this state, if the user performs an operation to change the display content of the main display unit 3, the information A3 is changed to another information: for example, information A4. Of course, it is possible to return the display content to the original state through an operation by the user. If the user performs an operation to change the display content of the auxiliary display unit 4, the information B3 is changed to another information: for example, information B4. Of course, it is possible to return the display content to the original state through an operation by the user.

The information A1, A2, A3 and A4 may be, for example, information obtained from various applications that operate under the OS. The information B1 and B2 may be, for example, various status information (e.g., keyboard shift information), information for operating the touch panel, the wireless signal level relating to WiFi (Wireless Fidelity), etc. of the main body 1. Alternatively, the information B1 and B2 may be all or part of display information that should be displayed in the main display unit 3 (e.g., a desktop screen on which icons are arranged, schedules and a slide show), or a reduced image of such information (a thumbnail image or the like). Further, it may be obtained while the OS is either running or stopped. The information B3 and B4 may be, for example, the content of received email, the number of received email items, the amount of electricity remaining in the battery or the date and time. Alternatively, the information B3 and B4 may be all or part of display information that should be displayed in the main display unit 3 (e.g., a desktop screen on which icons are arranged, schedules and a slide show), or a reduced image of such information (a thumbnail image or the like). In this case, the application, which should be provided for the display in the main display unit 3, is provided for the auxiliary display unit 4, and the information provided by the application is displayed on the auxiliary display unit 4. The information B3 and B4 may be completely the same as the above-mentioned information B1 and B2. Further, it may be obtained while the OS is either running or stopped.

FIG. 6 is a diagram showing an example of setting information relating to power control for use in the control unit 7 or the sub-CPU 43. The setting information can be preset by the user through the control unit 7 or the sub-CPU 43.

In the state where the auxiliary display unit 4 is mounted on the main body 1, power is supplied to the main body 1 or the main display unit 3 (or the display thereof) and also to the auxiliary display unit 4 (or the display thereof). In this state, the auxiliary display unit 4 is charged with power supplied from the main body 1. If the user performs an operation to change the power supply condition of the main display unit 3 to the power-saving mode or the power-stop mode, the main body 1 or the main display unit 3 (or the display thereof) is changed to the power-saving mode or the power-stop mode. Of course, it is possible to return the power supply condition to the original state through an operation of the user. If the user performs an operation to change the power supply condition of the auxiliary display unit 4 to the power-saving mode or the power-stop mode, the auxiliary display unit 4 (or the display thereof) is changed to the power-saving mode or the power-stop mode. Of course, it is possible to return the power supply condition to the original state through an operation by the user.

On the other hand, in the state where the auxiliary display unit 4 is separated from the main body 1, power is supplied to the main body 1 or the main display unit 3 (or the display thereof) and also to the auxiliary display unit 4 (or the display thereof). In this state, the auxiliary display unit 4 is driven by power charged in the battery 42. If the user performs an operation to change the power supply condition of the main display unit 3 to the power-saving mode or the power-stop mode, the main body 1 or the main display unit 3 (or the display thereof) is changed to the power-saving mode or the power-stop mode. Of course, it is possible to return the power supply condition to the original state through an operation of the user. If the user performs an operation to change the power supply condition of the auxiliary display unit 4 to the power-saving mode or the power-stop mode, the auxiliary display unit 4 (or the display thereof) is changed to the power-saving mode or the power-stop mode. Of course, it is possible to return the power supply condition to the original state through an operation by the user.

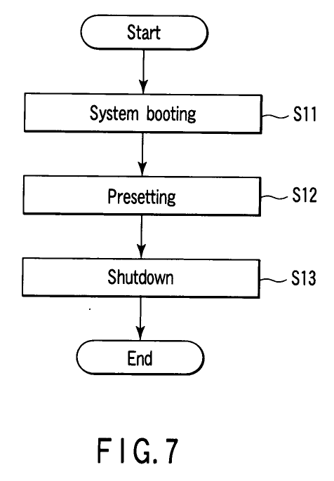

Operations relating to presetting will now be described with reference to FIG. 7.

The user operates the power supply button or the like, so that the information apparatus is powered on and the OS of the main body side is booted (block S11).

The user causes the main display unit 3 on the main body side to display a setting screen (the content corresponding to FIGS. 4 to 6), and determines setting content, thereby carrying out presetting (block S12). The content of the presetting is stored in a predetermined register or the like.

When the user performs a shutdown operation, a shutdown process is performed (block S13).

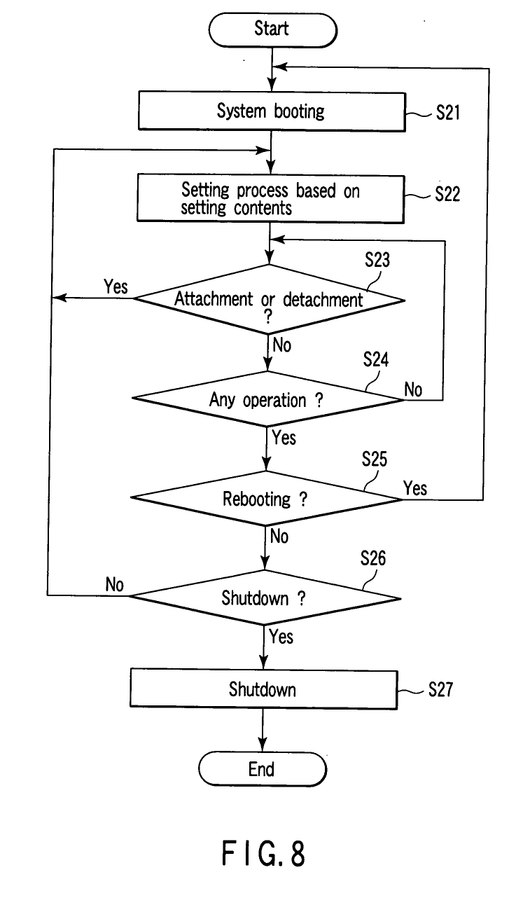

Operations relating to setting will be described with reference to FIG. 8. It is assumed that the presetting shown in FIG. 7 has been completed.

The user operates the power supply button or the like, so that the information apparatus is powered on and the OS of the main body side is booted (block S21).

The main display unit 3 and the auxiliary display unit 4 perform setting operations relating to the power supply condition and the display content based on the content of the prestored setting information (block S22).

Then, it is determined whether or not there is an operation of attaching or detaching the auxiliary display unit 4 is performed (block S23). If there is an operation of attaching or detaching the auxiliary display unit 4 is performed (Yes in block S23), the process returns to block S22. In block S22, setting operations in accordance with the state of attachment or detachment are performed. Further, it is determined whether or not the user performs any operation (block S24). If no operation is detected (No in block S24), the process returns to block S23 and the status monitoring is continued.

If an operation is detected in block S24 (Yes in block S24) and if the operation corresponds to rebooting (Yes in block S25), the process returns to block S21. If the operation corresponds to neither rebooting nor shutdown (No in block S26), it is determined that a resetting process is required and the process returns to block S22. If the operation corresponds to shutdown (Yes in block S26), the shutdown operation is executed (block S27).

As described above, even if the auxiliary display unit 4 is separated from the main body 1, it can be battery-operated without any problem. Further, the auxiliary display unit 4 can transmit various instructions to the main body 1 (or the cover 2) and display information transmitted from the main body 1 by wireless communication with the main body 1. Therefore, even when the information apparatus is contained in, for example, a bag, the user can see various information in the main body 1, including received mail, by referring to the auxiliary display unit 4 separated from the main body 1. Furthermore, the main display unit and the auxiliary display unit can display desired information upon request of the user, and power consumed by an unnecessary display unit can be saved.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An information apparatus, comprising:
a body;
a cover capable of being opened and closed with respect to the body;
a first display unit provided in the cover; and
a second display unit provided with a battery and attachable to and detachable from the body or the cover, the second display being capable of displaying information and charging the battery with power supplied from the body in an attached state, and displaying information with power of the battery in a detached state.

2. The information apparatus according to claim 1, wherein the second display unit has a wireless communication device and displays information obtained from the body through the wireless communication device in the detached state.

3. The information apparatus according to claim 2, wherein the second display unit displays information obtained from the body through the wireless communication device in the attached state.

4. The information apparatus according to claim 1, wherein an operating system of the body is running while the cover is closed with respect to the body, and the information apparatus further comprising a control unit which causes the second display unit to display information obtained while the operating system is running.

5. The information apparatus according to claim 1, wherein an operating system of the body is rebooted when a predetermined operation is performed while the cover is closed with respect to the body, and the information apparatus further comprising a controller which causes the second display unit to display information obtained when the operating system is rebooted.

6. The information apparatus according to claim 1, further comprising a control unit which performs control in which an operating condition of the body in the attached state of the second display unit differs from that in the detached state.

7. The information apparatus according to claim 1, further comprising a control unit which performs control in which a power supply condition of the body in the attached state of the second display unit differs from that in the detached state.

8. The information apparatus according to claim 1, further comprising a control unit which performs control in which a display content in the second display unit in the attached state of the second display unit differs from that in the detached state.

9. The information apparatus according to claim 1, wherein the second display unit has an input portion and transmits information input from the input portion to the body via a wireless communication device.

10. A display control method applied to an information apparatus including a body, a cover capable of being opened and closed with respect to the body, a first display unit provided in the cover, and a second display unit provided with a battery and attachable to and detachable from the body or the cover, the method comprising:
causing the second display unit to display first information while the second display unit is in an attached state; and
causing the second display unit to display second information, which is different from the first information, while the second display unit is in a detached state.

11. The display control method according to claim 10, further comprising setting the first information and the second information to be displayed in the second display unit.

12. The display control method according to claim 10, further comprising changing the first information displayed in the second display unit to set another information when a predetermined operation is performed while the second display unit is in the attached state.

13. The display control method according to claim 10, further comprising changing the second information displayed in the second display unit to set another information when a predetermined operation is performed while the second display unit is in the detached state.

14. The display control method according to claim 10, wherein the first information and the second information is obtained while an operating system of the information apparatus is running.

15. A display control method applied to an information apparatus including a body, a cover capable of being opened and closed with respect to the body, a first display unit provided in the cover, and a second display unit provided with a battery and attachable to and detachable from the body or the cover, the method comprising:
charging the second display unit with power supplied from the body, while the second display unit is in an attached state; and
causing the second display unit to display information with power obtained by the charging, while the second display unit is in a detached state.

16. The display control method according to claim 15, further comprising performing control in which the body is in a power-saving mode or a power-stop mode while the second display unit is in the detached state.

17. The display control method according to claim 15, further comprising performing control in which the body is in a power-saving mode or a power-stop mode when a predetermined operation is performed while the second display unit is in the detached state.
